(19) United States
(12) Patent Application Publication
(10) Pub. No.: US 2023/0378156 A1
(43) Pub. Date: Nov. 23, 2023

(54) INTEGRATED CIRCUIT INCLUDING MULTI-HEIGHT CELLS AND METHOD OF DESIGNING THE SAME

(71) Applicant: Samsung Electronics Co., Ltd., Suwon-si (KR)

(72) Inventors: Hyeongyu You, Suwon-si (KR); Jisu Yu, Suwon-si (KR); Geonwoo Nam, Suwon-si (KR); Jungho Do, Suwon-si (KR); Minjae Jeong, Suwon-si (KR); Jaehee Cho, Suwon-si (KR)

(21) Appl. No.: 18/303,607

(22) Filed: Apr. 20, 2023

(30) Foreign Application Priority Data
May 19, 2022 (KR) 10-2022-0061653
Aug. 19, 2022 (KR) 10-2022-0104328

(51) Int. Cl. H01L 27/02; G06F 30/31

(52) U.S. Cl. CPC H01L 27/0207; G06F 30/31

(57) ABSTRACT

An integrated circuit includes a first cell and a second cell respectively arranged in a first row and a second row that are adjacent to each other and extend in a first direction, and a third cell continuously arranged in the first row and the second row, wherein each of the first cell and the second cell comprises a first active pattern group including at least one active pattern that extends in the first direction and has a first conductivity type, the third cell comprises a second active pattern group including at least one active pattern that extends in the first direction in the first row and has the first conductivity type, and an effective channel width of the second active pattern group is greater than an effective channel width of the first active pattern group.

### CROSS-REFERENCE TO RELATED APPLICATIONS

This application is based on and claims priority under 35 U.S.C. § 119 to Korean Patent Application No. 10-2022-0061653, filed on May 19, 2022, and Korean Patent Application No. 10-2022-0104328, filed on Aug. 19, 2022, in the Korean Intellectual Property Office, the disclosures of which are incorporated by reference herein in their entireties.

### BACKGROUND

The inventive concept relates to an integrated circuit, and more particularly, to an integrated circuit including multi-height cells and a method of designing the integrated circuit.

Due to the development of a semiconductor process, sizes of devices included in an integrated circuit may be reduced. A device with a reduced size may provide a high degree of integration while having limited performance. A device with a size that is larger than the smallest device provided by a semiconductor process may be used for high performance, and accordingly, designing an integrated circuit with optimized performance and efficiency may be beneficial.

### SUMMARY

The inventive concept provides an integrated circuit with optimized performance and efficiency and a method of designing the integrated circuit.

According to an aspect of the inventive concept, an integrated circuit includes a first cell in a first row and a second cell in a second row, wherein the first and second rows are adjacent to each other and extend in a first direction, and a third cell in the first row and the second row, wherein each of the first cell and the second cell comprises a first active pattern group including at least one active pattern that extends in the first direction and has a first conductivity type, the third cell comprises a second active pattern group including at least one active pattern that extends in the first direction in the first row and has the first conductivity type, and an effective channel width of the second active pattern group is wider than an effective channel width of the first active pattern group. The third cell comprises portions provided in the first and second rows, respectively.

According to another aspect of the inventive concept, an integrated circuit includes a first cell in a first row and a second cell in a second row, wherein the first and second rows are adjacent to each other and extend in a first direction, a third cell in the first row and the second row, and a buffer cell in the first row and the second row, wherein the buffer cell is between the first cell and the third cell and between the second cell and the third cell, wherein the third cell comprises a first active pattern group including at least one active pattern that extends in the first direction in the first row and has a first conductivity type, the buffer cell comprises a second active pattern group including at least one active pattern that extends in the first direction in the first row and has the first conductivity type, and an effective channel width of the second active pattern group is narrower than an effective channel width of the first active pattern group. Each of the third cell and the buffer cell comprises portions provided in the first and second rows, respectively.

According to another aspect of the inventive concept, an integrated circuit includes cells arranged in a plurality of rows extending in a first direction and includes a first active pattern group including at least one active pattern that extends in the first direction in a first row among the plurality of rows and has a first conductivity type, a second active pattern group including at least one active pattern that extends in parallel to the first active pattern group in the first row and has a second conductivity type, and a third active pattern group including at least one active pattern that extends in the first direction in the first row and has the first conductivity type, wherein an effective channel width of the third active pattern group is wider than an effective channel width of the first active pattern group.

### BRIEF DESCRIPTION OF DRAWINGS

Embodiments will be more clearly understood from the following detailed description taken in conjunction with the accompanying drawings in which:

FIGS. 1A and 1B are plan views illustrating examples of layouts of an integrated circuit according to example embodiments;

FIGS. 2A to 2C are perspective views illustrating examples of devices according to example embodiments;

FIGS. 3A and 3B are plan views illustrating examples of cells according to example embodiments;

FIGS. 4A to 4E are plan views illustrating examples of layouts of an integrated circuit according to example embodiments;

FIG. 5 is a plan view illustrating doping regions for doping active patterns, according to an example embodiment;

FIG. 6A is a plan view illustrating a layout of an integrated circuit according to an example embodiment, and FIG. 6B is a plan view illustrating doping regions for doping active patterns, according to an example embodiment;

FIGS. 7A to 7E are plan views illustrating examples of layouts of an integrated circuit according to example embodiments;

FIGS. 8A to 8E are plan views illustrating examples of layouts of an integrated circuit according to example embodiments;

FIG. 9 is a flowchart illustrating a method of manufacturing an integrated circuit, according to an example embodiment;

FIG. 10 is a block diagram illustrating a system-on-chip according to an example embodiment; and

FIG. 11 is a block diagram illustrating a computing system including a memory storing a program, according to an example embodiment.

### DETAILED DESCRIPTION

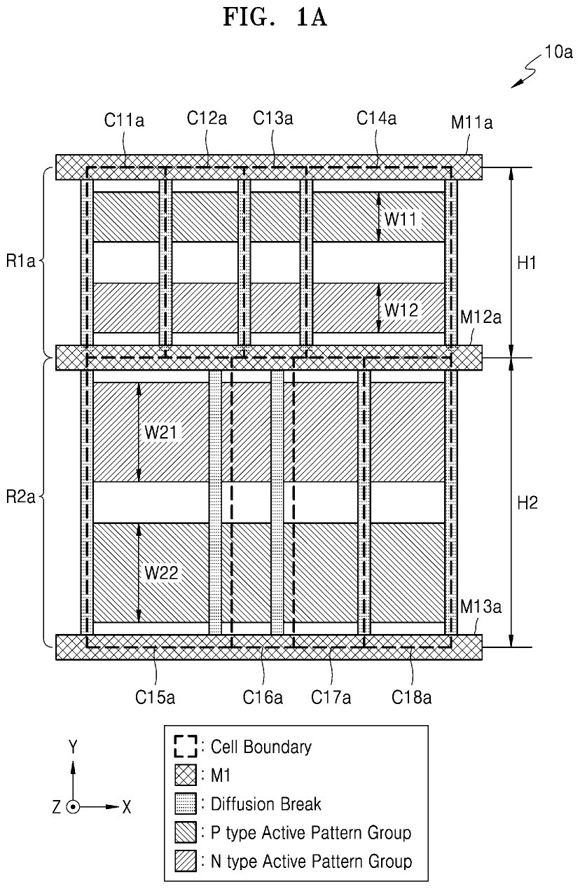

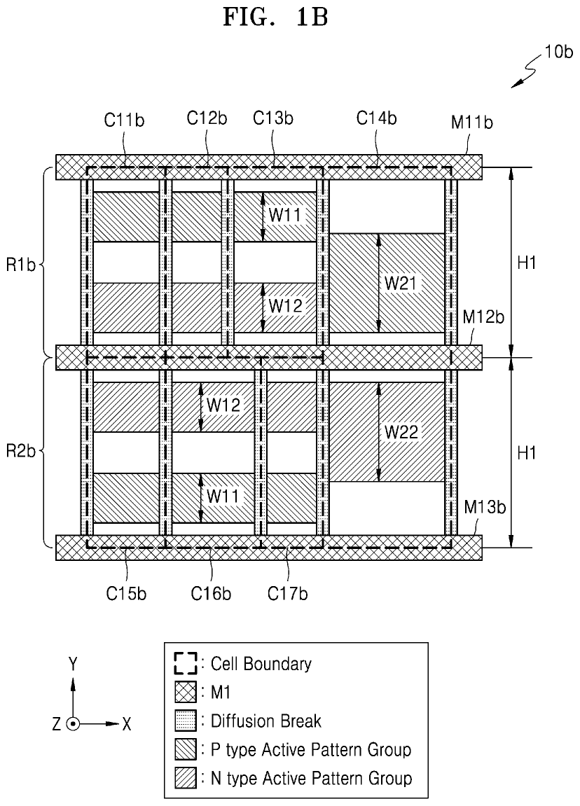

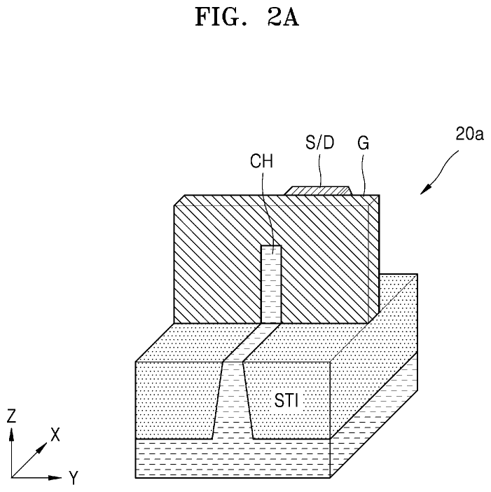

FIGS. 1A and 1B are plan views illustrating examples of layouts of an integrated circuit according to example embodiments. The plan views of FIGS. 1A and 1B respectively illustrate integrated circuits 10a and 10b in a plane consisting of an X axis and a Y axis. Redundancy in the description of FIGS. 1A and 1B is omitted.

Herein, an X-axis direction and a Y-axis direction may be referred to respectively as a first direction and a second direction, and a Z-axis direction may be referred to as a vertical direction or a third direction. A plane made up of the X axis and the Y axis may be referred to as a horizontal plane, and a component in a +Z direction relatively to another component may be referred to as being above another component, and a component in a −Z direction relatively to another component may be referred to as being below another component. In addition, an area of a component may be referred to as a size occupied by the component in a plane parallel to the horizontal plane, and a width of a component may be referred to as a length in a direction orthogonal to a direction in which the component is extended. A surface exposed in the +Z direction may be referred to as a top surface, a surface exposed in the −Z direction may be referred to as a bottom surface, and a surface exposed in the ±X direction or ±Y direction may be referred to as a lateral surface. In the drawings, only some layers or elements may be illustrated for the sake of convenience of illustration, and a via may be displayed even though the via is under a pattern of a wiring layer to indicate a connection between the pattern of the wiring layer and a sub-pattern. In addition, a pattern formed of a conductive material, such as a pattern of a wiring layer, may be referred to as a conductive pattern or may simply be referred to as a pattern.

Referring to FIG. 1A, an integrated circuit 10a may include a plurality of cells. For example, as illustrated in FIG. 1A, the integrated circuit 10a may include first to fourth cells C11a to C14a arranged in a first row R1a extending in the X-axis direction and may include fifth to eighth cells C15a to C18a arranged in a second row R2a extending in the X-axis direction. As used herein, “an element A extends in a direction D” (or similar language) may mean that the element A extends longitudinally in the direction D. A cell may be a unit of a layout included in an integrated circuit and may be referred to as a standard cell. A cell may include a transistor and may be designed to perform a predefined function. For example, the first cell C11a may have a predefined first height (i.e., a length in the Y-axis direction) H1, and the fifth cell C15a may have a predefined second height (i.e., a length in the Y-axis direction) H2. The integrated circuit 10a may have the second height H2 that is greater than the first height H1 (H2>H1). Cells arranged in one row, such as the first to eighth cells C11a to C18a, may each be referred to as a single-height cell, while a cell continuously arranged in two or more rows, such as a fourth cell C14b in FIG. 1B, may be referred to as a multi-height cell, and in particular, a cell continuously arranged in two rows may be referred to as a double-height cell. As used herein, “a cell continuously arranged in multiple rows” (or similar language) refers to a cell including multiple portions included in the multiple rows, respectively. As illustrated in FIG. 1B, the fourth cell C14b is a double-height cell and includes two portions included in two rows, respectively.

Diffusion breaks may be arranged between adjacent cells (e.g., the first and second cells C11a and C12a) in the X-axis direction, and cells may be separated by the diffusion breaks. For example, as illustrated in FIG. 1A, diffusion breaks may extend in the Y-axis direction at boundaries of the first to eighth cells C11a to C18a.

The integrated circuit 10a may include a power rail for supplying power to cells. For example, as illustrated in FIG. 1A, the integrated circuit 10a may include first to third patterns M11a to M13a extending in parallel to each other in the X-axis direction in an M1 layer (e.g., a first metal layer or a first wiring layer). Each of the first and second patterns M11a and M12a may provide a positive supply voltage or a negative supply voltage (or a ground potential) to the first to fourth cells C11a to C14a in the first row R1a. In addition, each of the second and third patterns M12a and M13a may provide a positive supply voltage or a negative supply voltage to the fifth to eighth cells C15a to C18a in the second row R2a. Accordingly, the first to fourth cells C11a to C14a in the first row R1a may share the second pattern M12a with the fifth to eighth cells C15a to C18a in the second row R2a.

The integrated circuit 10a may include an active pattern extending in the X-axis direction, and the active pattern may form a transistor with a gate electrode that may extend in the Y-axis direction. For example, as illustrated in FIG. 1A, a P-type active pattern group and an N-type active pattern group may extend in the X-axis direction in the first row R1a. In some embodiments, a width W11 of the P-type active pattern group may equal to the width W12 of the N-type active pattern group. In addition, the N-type active pattern group and the P-type active pattern group having a width W22 may extend in the X-axis direction in the second row R2a. In some embodiments, a width W21 of the N-type active pattern group may be equal to the width W22 of the P-type active pattern group.

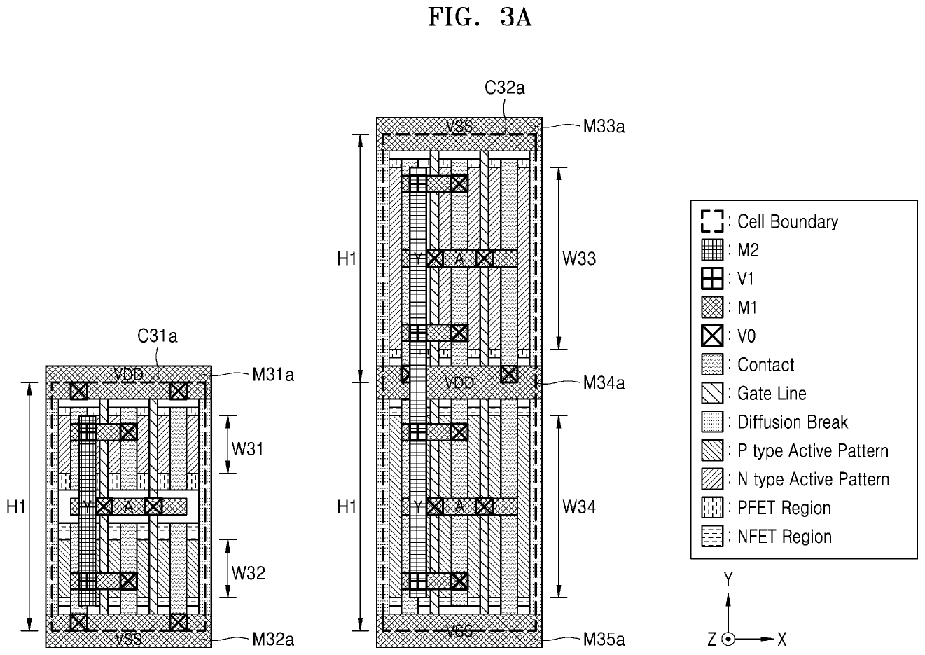

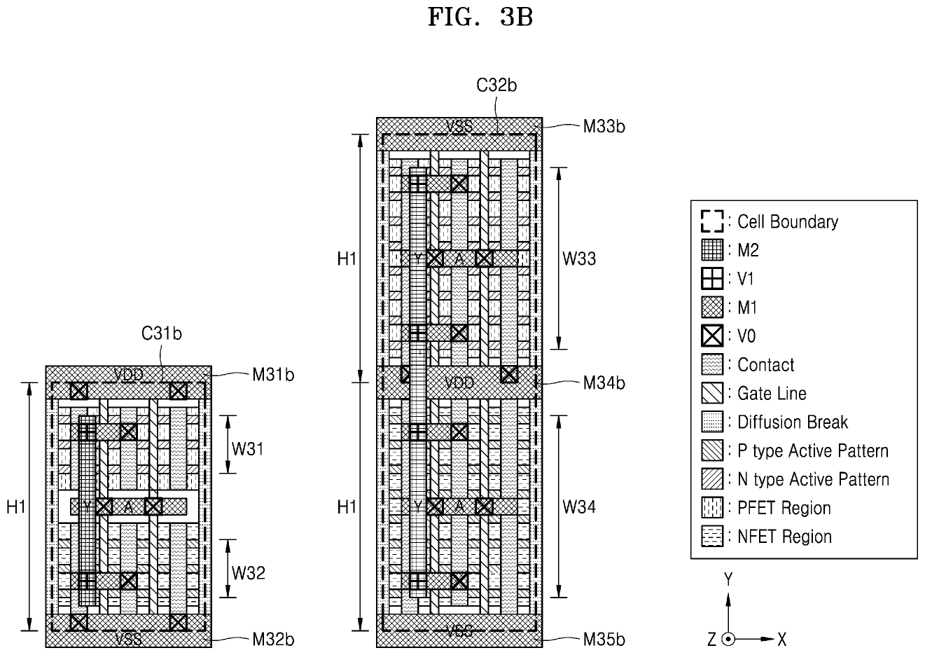

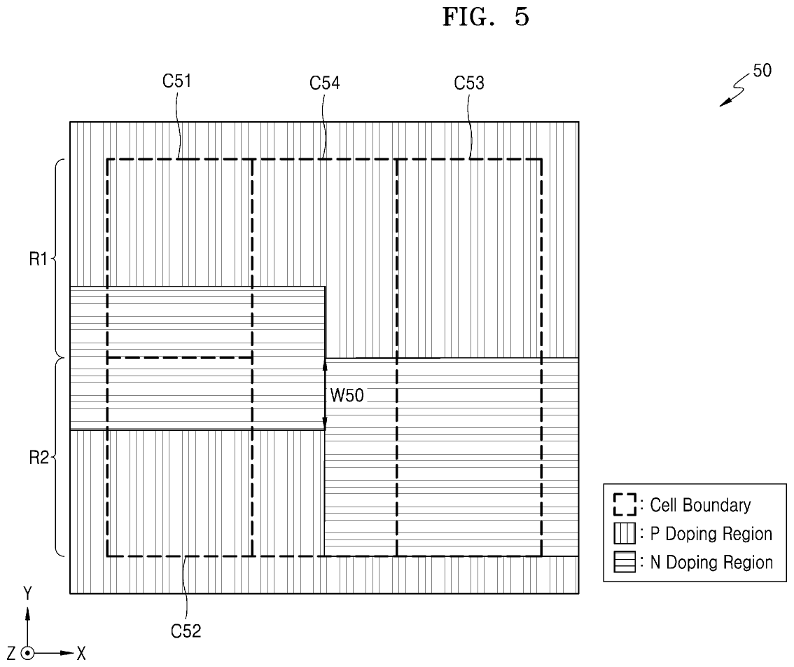

One active pattern group may include at least one active pattern extending in the X-axis direction. For example, the active pattern group may also include one active pattern extending in the X-axis direction having a width of an active pattern group as described below with reference to FIG. 3A and may also include a plurality of active patterns extending in parallel to each other in a plurality of X-axis directions as described below with reference to FIG. 3B. In some embodiments, a conductivity type of the active pattern may be determined by an implantation process. For example, as described below with reference to FIG. 5, different dopants may be respectively implanted into the active patterns.

A cell may include an active pattern group and a transistor formed by a gate electrode, and an effective channel width of the transistor may depend on a width of the active pattern group. For example, the width W21 of the N-type active pattern group and the width W22 of the P-type active pattern group extending in the second row R2a having the second height H2 may be greater than the width W11 of the P-type active pattern group and the width W12 of the N-type active pattern group extending in the first row R1a having the first height H1. Accordingly, effective channel widths of transistors included in the fifth to eighth cells C15a to C18a may be greater than effective channel widths of transistors included in the first to fourth cells C11a to C14a, and thus, the fifth to eighth cells C15a to C18a may have higher current driving capability, a higher speed and/or more power consumption. Accordingly, cells requiring a high operating speed (e.g., critical path) may be arranged in the second row R2a, and other cells may be arranged in the first row R1a. As illustrated in FIG. 1A, only cells having the second height H2 may be in the second row R2a, and the cells in the second row R2a may be used even in an operation that does not require a high speed. For example, even when only the fifth cell C15a requires a high speed, the sixth to eighth cells C16a to C18a may be in the second row R2a, and thus, the integrated circuit 10a may not have optimal area (or a degree of integration) and power consumption.

Referring to FIG. 1B, an integrated circuit 10b may include first to third cells C11b to C13b arranged in a first row Rib, include fifth to seventh cells C15b to C17b arranged in the second row R2b, and include a fourth cell C14b continuously arranged in the first and second rows R1b and R2b. In order to supply power to the cells of the integrated circuit 10b, the first to third patterns M11b to M13b may extend in parallel to each other in the X-axis direction. As illustrated in FIG. 1B, a second pattern M12b may pass through the fourth cell C14b. The first row R1b and the second row R2b may each have the first height H1. A P-type active pattern group extending in the X-axis direction in the first row R1b and a P-type active pattern group extending in the X-axis direction in the second row R2b may each have a width W11. In addition, an N-type active pattern group extending in the X-axis direction in the first row R1b and an N-type active pattern group extending in the X-axis direction in the second row R2b may each have a width W12.

The integrated circuit 10b may include multi-height cells for high performance. For example, as illustrated in FIG. 1B, the fourth cell C14b may be a multi-height cell that is continuously arranged in the first and second rows R1b and R2b, and may include a P-type active pattern group extending in the X-axis direction in the first row R1b and an N-type active pattern group extending in the X-axis direction in the second row R2b. A width W21 of the P-type active pattern group of the fourth cell C14b may be greater than a width W11 of each of the P-type active pattern groups included in the first to third cells C11b to C13b and the fifth to seventh cells C15b to C17b. In addition, a width W22 of the N-type active pattern group of the fourth cell C14b may be greater than a width W12 of each of the pattern groups included in the first to third cells C11b to C13b and the fifth to seventh cells C15b to C17b.

Compared to the integrated circuit 10a of FIG. 1A, the integrated circuit 10b of FIG. 1B may include only the fourth cell C14b, which is a multi-height cell for a high speed operation, and the other cells may be single-height cells having the first height H1. Accordingly, the integrated circuit 10b of FIG. 1B may have optimal area and power consumption as well as performance.

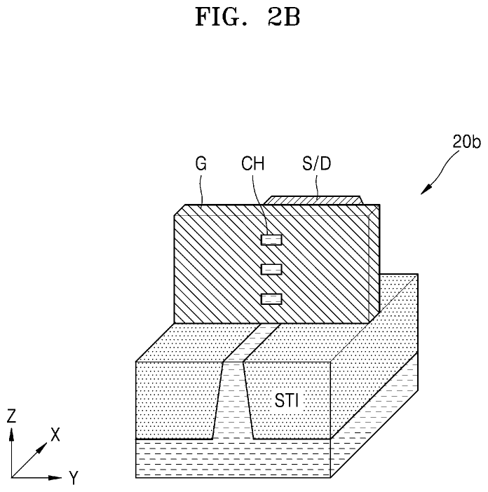

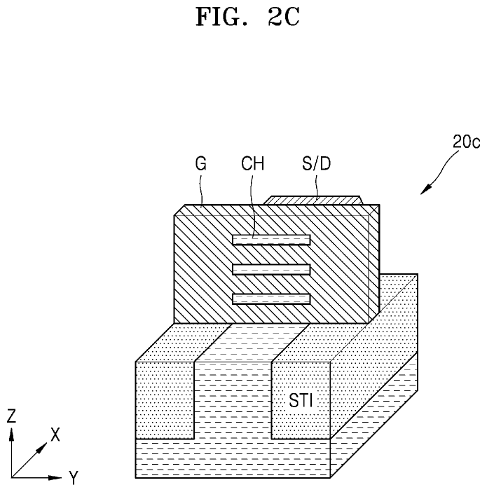

FIGS. 2A to 2C are perspective views illustrating examples of devices according to example embodiments. For example, FIG. 2A illustrates a fin field effect transistor (FinFET) 20a, FIG. 2B illustrates a gate-all-around field effect transistor (GAAFET) 20b, and FIG. 2C illustrates a multi-bridge channel field effect (MBCFET) transistor 20c. For the sake of convenience of illustration, FIGS. 2A to 2C illustrate a state in which one of two source/drain regions is removed.

Referring to FIG. 2A, the FinFET 20a may include a fin-shaped active pattern extending in the X-axis direction between shallow trench isolations (STIs) and a gate G extending in the Y-axis direction. Source/drains S/D may be respectively formed on both sides of the gate G, and accordingly, a source and a drain may be separated from each other in the X-axis direction. An insulating layer may be formed between a channel CH and the gate G, and an effective channel width of the FinFET 20a may correspond to a length in the Y-axis direction and a length in the Z-axis direction of the channel CH in contact with the insulating layer. In some embodiments, the FinFET 20a may include a plurality of active patterns separated from each other in the Y-axis direction and the gate G. In the FinFET 20a, the active pattern, that is, a width of a fin, may correspond to a length in the Y-axis direction. In some embodiments, when the fin is doped with an N-type impurity and the source/drain S/D is doped with a P⁺-type impurity, the FinFET 20a may correspond to a p-type field effect transistor (PFET), and when the fin is doped with a P-type impurity and the source/drain S/D is doped with an N⁺-type impurity, the FinFET 20a may correspond to an n-type field effect transistor (NFET). As used herein, the term “gate” is interchangeable with “gate electrode.”

Referring to FIG. 2B, the GAAFET 20b may include active patterns (e.g., nanowires) separated from each other in the Z-axis direction and extending in the X-axis direction and a gate G extending in the Y-axis direction. Source/drains S/D may be respectively formed on both sides of the gate G, and accordingly, a source and a drain may be separated from each other in the X-axis direction. An insulating layer may be formed between a channel CH and the gate G, and an effective channel width of the GAAFET 20b may correspond to a length in the Y-axis direction and a length in the Z-axis direction of the channel CH in contact with the insulating layer. It is noted that the number of active patterns (e.g., nanowires) included in the GAAFET 20b is not limited to the number illustrated in FIG. 2B. A width of the active pattern formed in the GAAFET 20b, that is, a width of the nanowire in some embodiments, may correspond to a length in the Y-axis direction. In some embodiments, where the active pattern (e.g., the nanowire) is doped with an N-type impurity and the source/drain S/D is doped with a P⁺-type impurity, the GAAFET 20b may correspond to a PFET, wherein, when the active pattern (e.g., the nanowire) is doped with a P-type impurity and the source/drain S/D is doped with an N⁺-type impurity, the GAAFET 20b may correspond to an NFET.

Referring to FIG. 2C, the MBCFET 20c may be formed from active patterns (e.g., nanosheets) separated from each other in the Z-axis direction and extending in the X-axis direction and a gate G extending in the Y-axis direction. Source/drains S/D may be respectively formed on both sides of the gate G, and accordingly, a source and a drain may be separated from each other in the Y-axis direction. An insulating layer may be formed between a channel CH and the gate G, and an effective channel width of the MBCFET 20c may correspond to a length in the Y-axis direction and a length in the Z-axis direction of the channel CH in contact with the insulating layer. It is noted that the number of active patterns (e.g., nanosheets) included in the MBCFET 20c is not limited to the number illustrated in FIG. 2C. A width of the active pattern formed in the MBCFET 20c, that is, a width of the nanosheet in some embodiments, may correspond to the length in the Y-axis direction. In some embodiments, when the active pattern (e.g., the nanosheet) is doped with an N-type impurity and the source/drain S/D is doped with a P⁺-type impurity, the MBCFET 20c may correspond to a PFET, and when the active pattern (e.g., the nanosheet) is doped with a P-type impurity and the source/drain S/D is doped with an N⁺-type impurity, the MBCFET 20c may correspond to an NFET.

Hereinafter, example embodiments will be mainly described with reference to the FinFET 20a and the MBCFET 20c, but the structures of the transistors included in cells are not limited thereto. For example, a cell may include a ForkFET having a structure in which the N-type transistor is closer to the P-type transistor because active patterns (e.g., nanosheets) for a P-type transistor and active patterns (e.g., nanosheets) for an N-type transistor are separated by dielectric walls. In addition, a cell may also include a bipolar junction transistor as well as an FET, such as a complementary FET (CFET), a negative capacitance FET (NCFET), or a carbon nanotube (CNT) FET.

FIGS. 3A and 3B are plan views illustrating examples of a cell according to example embodiments. The plan view of FIG. 3A illustrates first and second cells C31a and C32a functioning as inverters, each having an input A and an output Y, and the plan view of FIG. 3B illustrates first and second cells C31b and C32b functioning as inverters, each having an input A and an output Y. In FIGS. 3A and 3B, the illustration of source/drain regions is omitted for the sake of convenience of illustration. Hereinafter, redundancy in the description of FIGS. 3A and 3B is omitted.

Referring to FIG. 3A, the first cell C31a may have a first height H1 as a single-height cell and may include an MBCFET. For example, the first cell C31a may include a PFET formed from a nanosheet (i.e., an active pattern) having a first width W31 and a gate electrode extending in the Y-axis direction and may include an NFET formed from a nanosheet (i.e., an active pattern) having a width W32 and a gate electrode extending in the Y-axis direction. First and second patterns M31a and M32a of an M1 layer may respectively provide a positive supply voltage VDD and a negative supply voltage VSS to the first cell C31a and may extend in parallel to each other in the X-axis direction on boundaries of the first cell C31a.

The second cell C32a may have a height corresponding to twice the first height H1 as a multi-height cell and include an MBCFET. For example, the second cell C32a may include a PFET formed from a nanosheet (i.e., an active pattern) having a third width W33 and a gate electrode extending in the Y-axis direction and include an NFET formed from a nanosheet (i.e., an active pattern) having a fourth width W34 and a gate electrode extending in the Y-axis direction. The third width W33 may be greater than the first width W31, and the fourth width W34 may be greater than the second width W32. Accordingly, an inverter of the second cell C32a may have a higher speed and power consumption than an inverter of the first cell C31a. The third and fifth patterns M33a and M35a of the M1 layer may provide a negative supply voltage VSS to the second cell C32a and may extend in parallel to each other in the X-axis direction on boundaries of the second cell C32a. The fourth pattern M34a of the M1 layer may provide a positive supply voltage VDD to the second cell C32a and extend through the second cell C32a in the X-axis direction.

Referring to FIG. 3B, the first cell C31b may have the first height H1 as a single-height cell and may include a FinFET. For example, the first cell C31b may include a PFET formed from fins (i.e., active patterns) included in an active pattern group having a first width W31 and a gate electrode extending in the Y-axis direction and include an NFET formed from fins (i.e., active patterns) included in an active pattern group having a second width W32 and a gate electrode extending in the Y-axis direction. The first and second patterns M31b and M32b of the M1 layer may respectively provide the positive supply voltage VDD and the negative supply voltage VSS to the first cell C31b, and may extend in parallel to each other in the X-axis direction on boundaries of the first cell C31b.

The second cell C32b may have a height corresponding to twice the first height H1 as a multi-height cell and may include a FinFET. For example, the second cell C32b may include a PFET formed from fins (i.e., active patterns) included in an active pattern group having a third width W33 and a gate electrode extending in the Y-axis direction and may include an NFET formed from fins (i.e., active patterns) included in an active pattern group having a fourth width W34 and a gate electrode extending in the Y-axis direction. The number of fins included in the active pattern group having the third width W33 may be greater than the number of fins included in the active pattern group having the first width W31, and the number of fins included in the active pattern group having the fourth width W34 may be greater than the number of fins included in the active pattern group having the second width W32. Accordingly, an inverter of the second cell C32b may have a higher speed and power consumption than an inverter of the first cell C31b. The third and fifth patterns M33b and M35b of the M1 layer may provide the negative supply voltage VSS to the second cell C32b and may extend in parallel to each other in the X-axis direction on boundaries of the second cell C32b. The fourth pattern M34b of the M1 layer may provide the positive supply voltage VDD to the second cell C32b and extend through the second cell C32b in the X-axis direction.

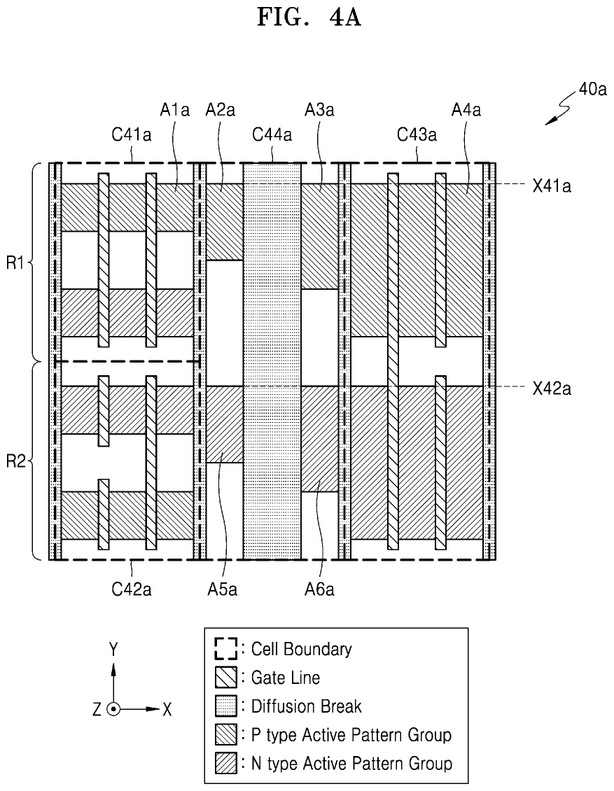

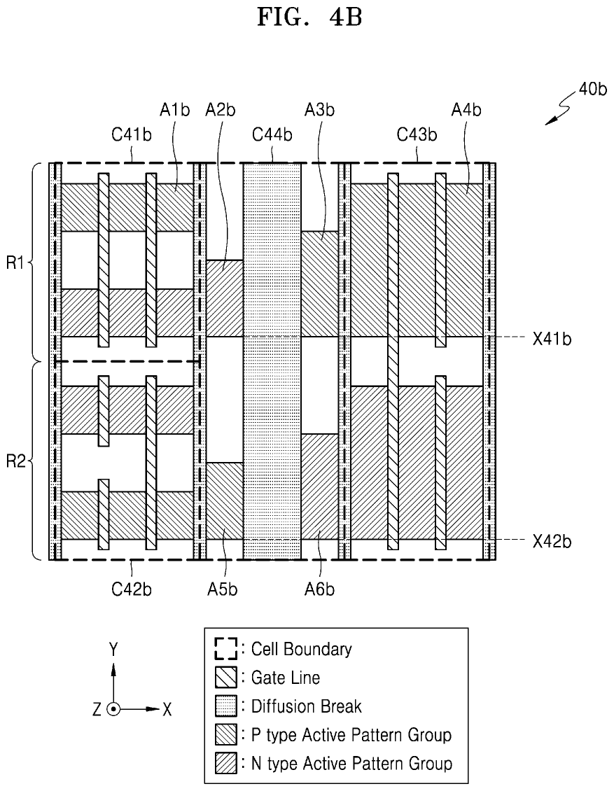

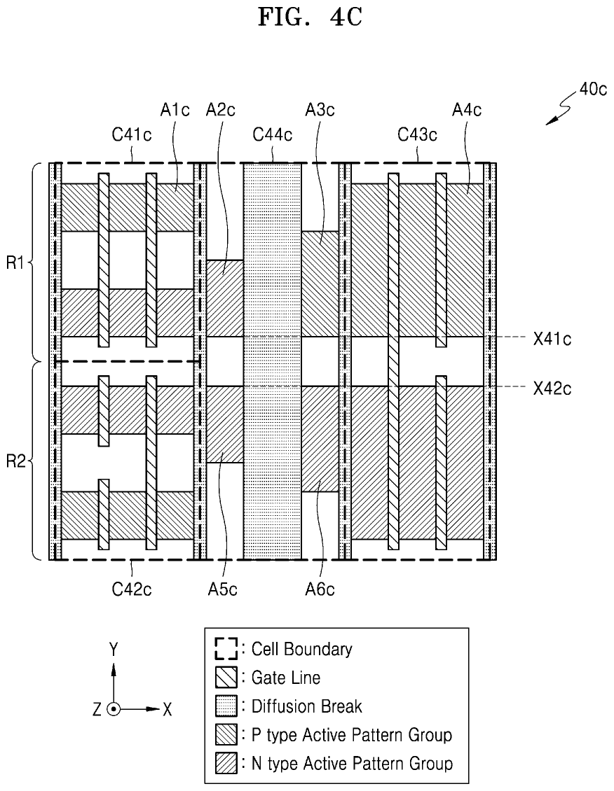

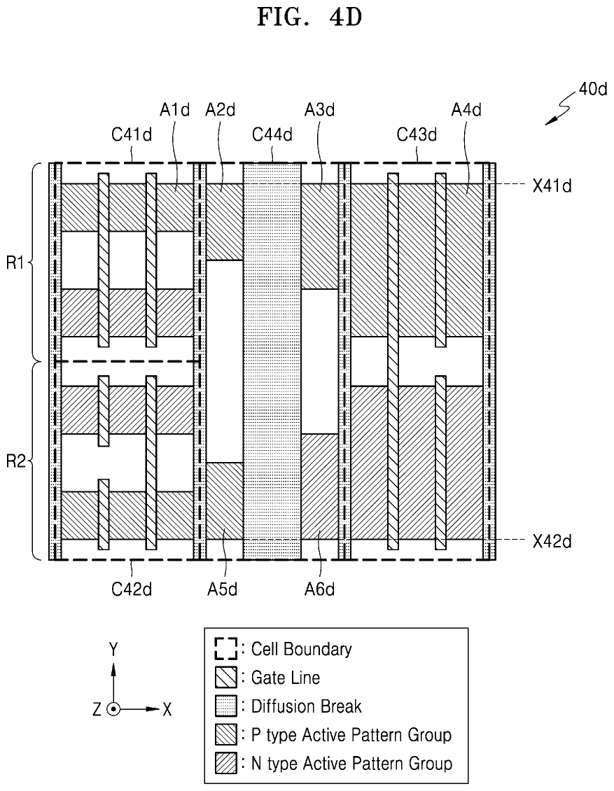

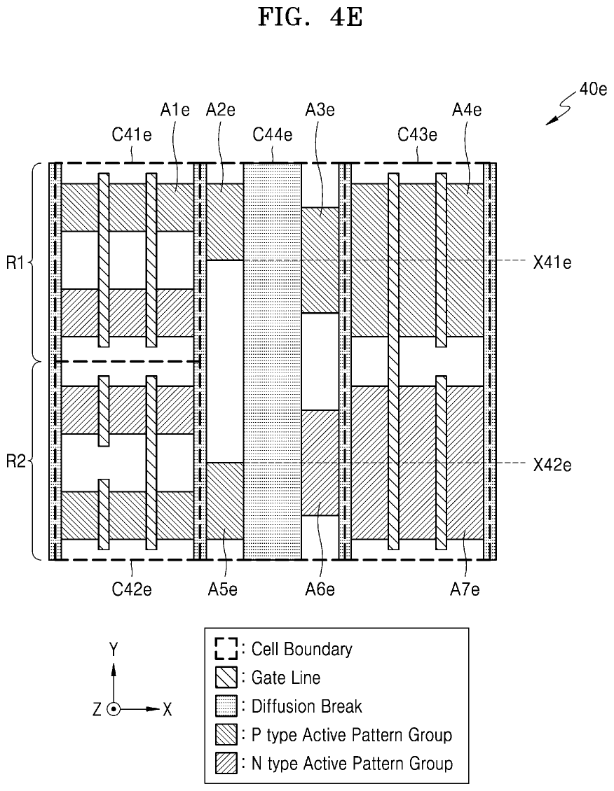

FIGS. 4A to 4E are plan views illustrating examples of layouts of an integrated circuit according to example embodiments. The plan views of FIGS. 4A to 4E illustrate various structures of a buffer cell between a single-height cell and a multi-height cell. Hereinafter, redundancy in the description of FIGS. 4A to 4E is omitted.

Referring to FIG. 4A, an integrated circuit 40a may include a first cell C41a in a first row R1, a second cell C42a in a second row R2, and third and fourth cells C43a and C44a continuously arranged in the first and second rows R1 and R2. As described above with reference to the drawings, the third cell C43a, which is a multi-height cell may include an active pattern group having a wide effective channel width, and accordingly, the third cell C43a may provide higher performance than the first and second cells C41a and C42a.

The fourth cell C44a may be between the first cell C41a and the third cell C43a and between the second cell C42a and the third cell C43a. The fourth cell C44a may be a multi-height cell between a single-height cell and the multi-height cell and may be referred to as a buffer cell. The buffer cell may have a structure required to switch between a single-height cell and a multi-height cell due to a semiconductor process. For example, the fourth cell C44a may include, in the first row R1, second and third active pattern groups A2a and A3a, each having a width that is greater than a width of a first active pattern group Ala included in the first cell C41a and is less than a width of a fourth active pattern group A4a included in the third cell C43a. Similarly, the second row R2 of the fourth cell C44a may include fifth and sixth active pattern groups A5a and A6a. The second and third active pattern groups A2a and A3a may have boundaries overlapping a first line X41a extending in the X-axis direction and may be between the first line X41a and the second row R2. In addition, the fifth and sixth active pattern groups A5a and A6a may have boundaries overlapping a second line X42a extending in the X-axis direction and the second line X42a may be between the fifth and sixth active pattern groups A5a and A6a and the first row R1. Although not illustrated in FIG. 4A, a buffer cell (e.g., C44a) may be adjacent to a +X-axis direction of a multi-height cell (e.g., C43a), and single-height cells (e.g., C41a and C42a) may be in the +X-axis direction of the buffer cell (e.g., C44a). As used herein, “boundaries overlapping a line L extending in an X-axis direction” (or similar language)” may refer to boundaries aligned along an imaginary line that extends in the X-axis direction.

In some embodiments, the buffer cell may be a tie cell. The tie cell may refer to a cell that generates an output signal of a constant level. For example, the tie cell may generate a signal having a voltage (e.g., a voltage that approximates a positive supply voltage) corresponding to a logic high level and/or a signal having a voltage (e.g., a voltage that approximates a negative supply voltage or a ground potential) corresponding to a logic low level. To this end, the tie cell may include at least one element. A cell receiving an input signal of a constant level may be coupled to a tie cell instead of being directly coupled to a positive supply voltage or a negative supply voltage, and accordingly, latch-up due to electrostatic discharge (ESD) or so on may be reduced or prevented. As a buffer cell functions as a tie cell, a space for a separate tie cell may be removed, and thus, the efficiency of the integrated circuit 40a may be further increased.

The fourth cell C44a may include a diffusion break (DB) extending in the Y-axis direction between the second and third active pattern groups A2a and A3a and between the fifth and sixth active pattern groups A5a and A6a. The second and third active pattern groups A2a and A3a and the fifth and sixth active pattern groups A5a and A6a may be terminated by the DB. In some embodiments, the DB may be a double diffusion break having a width (i.e., a length in the X-axis direction) corresponding to two adjacent gate electrodes, and a diffusion break extending in the Y-axis direction between cells may be a single diffusion break having a width (i.e., a length in the X-axis direction) corresponding to the gate electrode. A pitch between adjacent gate electrodes in the X-axis direction may be referred to as a contacted poly pitch (CPP), and in some embodiments, the fourth cell C44a may have a length in the X-axis direction corresponding to 3CPP.

Referring to FIG. 4B, the integrated circuit 40b may include a first cell C41b in a first row R1, a second cell C42b in a second row R2, and third and fourth cells C43b and C44b continuously arranged in the first and second rows R1 and R2. The fourth cell C44b may be a buffer cell and may be between the first cell C41b and the third cell C43b and between the second cell C42b and the third cell C43b. As illustrated in FIG. 4B, the fourth cell C44b may include, in the first row R1, second and third active pattern groups A2b and A3b, each having a width that is greater than a width of a first active pattern group Alb included in the first cell C41b and is less than a width of a fourth active pattern group A4b included in the third cell C43b. Similarly, the fourth cell C44b may include fifth and sixth active pattern groups A5b and A6b in the second row R2. The second and third active pattern groups A2b and A3b may have boundaries overlapping a first line X41b extending in the X-axis direction, and the first line X41b may be between the second and third active pattern groups A2b and A3b and the second row R2. In addition, the fifth and sixth active pattern groups A5b and A6b may have boundaries overlapping a second line X42b extending in the X-axis direction and may be between the second line X42b and the first row R1.

Referring to FIG. 4C, an integrated circuit 40c may include a first cell C41c in a first row R1, a second cell C42c in a second row R2, and third and fourth cells C43c and C44c continuously arranged in the first and second rows R1 and R2. The fourth cell C44c may be a buffer cell and may be between the first cell C41c and the third cell C43c and between the second cell C42c and the third cell C43c. As illustrated in FIG. 4C, the fourth cell C44c may include, in the first row R1, second and third active pattern groups A2c and A3c, each having a width that is greater than a width of a first active pattern group A1c included in the first cell C41c and is less than a width of a fourth active pattern group A4c included in the third cell C43c. Similarly, the fourth cell C44c may include fifth and sixth active pattern groups A5c and A6c in the second row R2. The second and third active pattern groups A2c and A3c may have boundaries overlapping a first line X41c extending in the X-axis direction, and the first line X41c may be between the second and third active pattern groups A2c and A3c and the second row R2. In addition, the fifth and sixth active pattern groups A5c and A6c may have boundaries overlapping a second line X42c extending in the X-axis direction and the second line X42c may be between the fifth and sixth active pattern groups A5c and A6c and the first row R1. In the fourth cell C44c, the aligned active pattern groups as illustrated in FIG. 4C may be referred to as in-bounded.

Referring to FIG. 4D, an integrated circuit 40d may include a first cell C41d in a first row R1, a second cell C42d in a second row R2, and third and fourth cells C43d and C44d continuously arranged in the first and second rows R1 and R2. The fourth cell C44d may be a buffer cell and may be between the first cell C41d and the third cell C43d and between the second cell C42d and the third cell C43d. As illustrated in FIG. 4D, the fourth cell C44d may include, in the first row R1, second and third active pattern groups A2d and A3d, each having a width that is greater than a width of a first active pattern group A1d included in the first cell C41d and is less than a width of a fourth active pattern group A4d included in the third cell C43d. Similarly, the fourth cell C44d may include fifth and sixth active pattern groups A5d and A6d in the second row R2. The second and third active pattern groups A2d and A3d may have boundaries overlapping a first line X41d extending in the X-axis direction and may be between the first line X41d and the second row R2. In addition, the fifth and sixth active pattern groups A5d and A6d may have boundaries overlapping a second line X42d extending in the X-axis direction and may be between the second line X42d and the first row R1. In the fourth cell C44d, the aligned active pattern groups as illustrated in FIG. 4D may be referred to as out-bounded.

Referring to FIG. 4E, an integrated circuit 40e may include a first cell C41e in a first row R1, a second cell C42e in a second row R2, and third and fourth cells C43e and C44e continuously arranged in the first and second rows R1 and R2. The fourth cell C44e may be a buffer cell and may be between the first cell C41e and the third cell C43e and between the second cell C42e and the third cell C43e. As illustrated in FIG. 4E, the fourth cell C44e may include, in the first row R1, second and third active pattern groups A2e and A3e, each having a width that is greater than a width of a first active pattern group Ale included in the first cell C41e and is less than a width of a fourth active pattern group A4e included in the third cell C43e. Similarly, the fourth cell C44e may include fifth and sixth active pattern groups A5e and A6e in the second row R2. The third and fourth active pattern groups A3e and A4e may have centers (e.g., centers in the Y-axis direction) overlapping the first line X41e extending in the X-axis direction. In addition, sixth and seventh active pattern groups A6e and Ale may have centers (e.g., centers in the Y-axis direction) overlapping the first line X41e extending in the X-axis direction. As illustrated in FIG. 4E, active pattern groups aligned in the first line X41e or the second line X42e may be referred to as mid-bounded. As used herein, “centers overlapping a line M extending in an X-axis direction” (or similar language)” may refer to centers that are aligned along the X-axis direction.

FIG. 5 is a plan view illustrating doping regions for doping active patterns, according to an example embodiment. In some embodiments, the doping regions illustrated in FIG. 5 may be used for doping active patterns included in each of the integrated circuits 40a to 40e of FIGS. 4A to 4E. As described above with reference to FIGS. 2A to 2C, the type of a transistor may be determined according to a conductivity type of the active pattern.

Referring to FIG. 5, an integrated circuit 50 may include a first cell C51 in a first row R1, a second cell C52 in a second row R2, and third and fourth cells C53 and C54 continuously arranged in the first and second rows R1 and R2. An active pattern group may be doped by a P-doped region or an N-doped region extending in the X-axis direction. As illustrated in FIGS. 4A to 4E, in order to dope the active pattern groups, a boundary between the P-doped region and the N-doped region in the first and second cells C51 and C52, which are single-height cells, may exist within the first row R1 and the second row R2, and the boundary between the P-doped region and the N-doped region in the third cell C53, which is a multi-height cell, may exist at a boundary between the first and second rows R1 and R2. To this end, jogging of the P-doped region and the N-doped region may occur in a buffer cell, that is, the fourth cell C54.

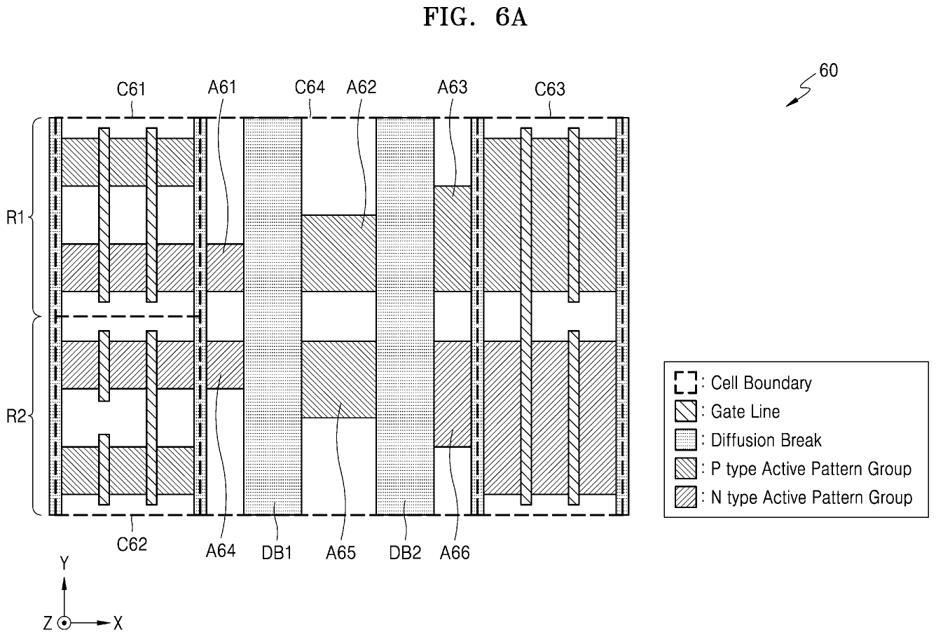

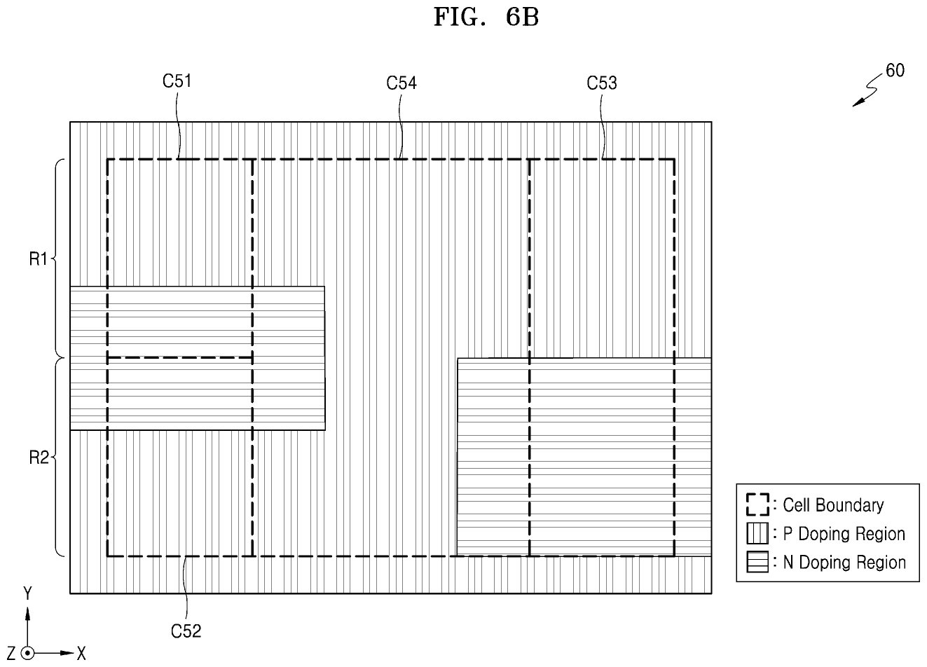

In some embodiments, a semiconductor process may define the minimum width of a doping region, that is, the minimum length in the Y-axis direction. As illustrated in FIG. 5, the N-doped region may include a portion having a width W50 in the fourth cell C54. When the width W50 is less than the minimum width defined by the semiconductor process, an extended buffer cell may be used as described below with reference to FIGS. 6A and 6B.

FIG. 6A is a plan view illustrating a layout of an integrated circuit according to an example embodiment, and FIG. 6B is a plan view illustrating doping regions for doping active patterns, according to an example embodiment. The doping regions illustrated in FIG. 6B may be regions for doping active patterns included in an integrated circuit 60 of FIG. 6A.

Referring to FIG. 6A, the integrated circuit 60 may include a first cell C61 in a first row R1, a second cell C62 in a second row R2, and third and fourth cells C63 and C64 continuously arranged in the first and second rows R1 and R2. The fourth cell C64, which is a buffer cell, may include first to third active pattern groups A61 to A63 in the first row R1 and include fourth to sixth active pattern groups A64 to A66 in the second row R2. In addition, the fourth cell C64 may include first and second diffusion breaks DB1 and DB2 extending in the Y-axis direction. The first diffusion break DB1 may terminate the first and second active pattern groups A61 and A62 and the fourth and fifth active pattern groups A64 and A65, and the second diffusion break DB2 may terminate the second and third active pattern groups A62 and A63 and the fifth and sixth active pattern groups A65 and A66. In some embodiments, each of the first and second diffusion breaks DB1 and DB2 may be a double diffusion break.

Referring to FIG. 6B, an active pattern group may be doped by a P-doped region or an N-doped region extending in the X-axis direction. Differently from that illustrated in FIG. 5, the N-doped regions may not be connected in the fourth cell C54, that is, the buffer cell, and the N-doped region as well as the P-doped region may have a width that is greater than or equal to the minimum width defined by the semiconductor process. Accordingly, the second and fifth active pattern groups A62 and A65 of FIG. 6A may be doped with the same conductivity type impurity, that is, a P-type impurity.

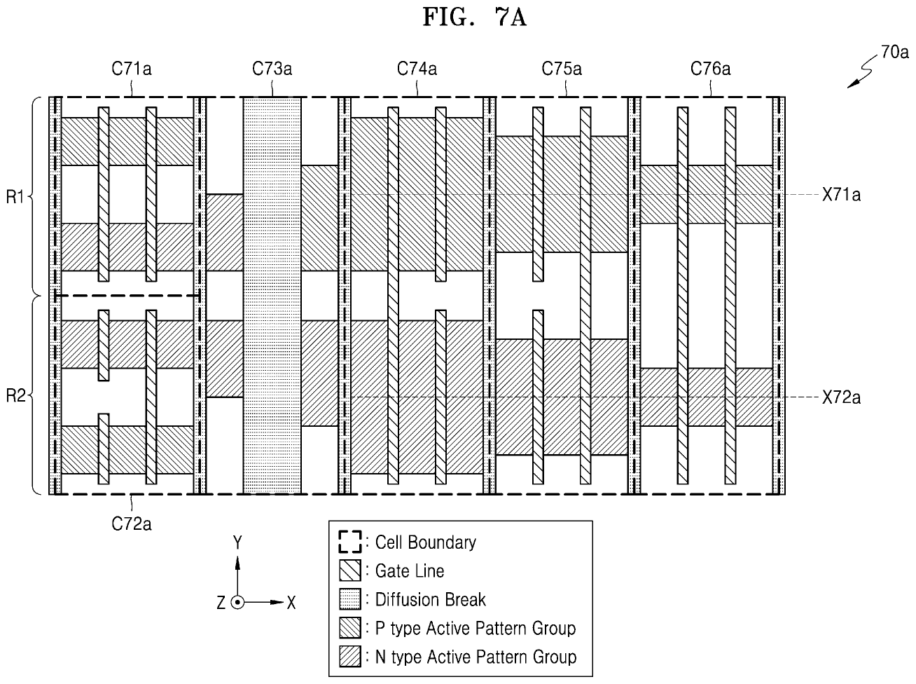

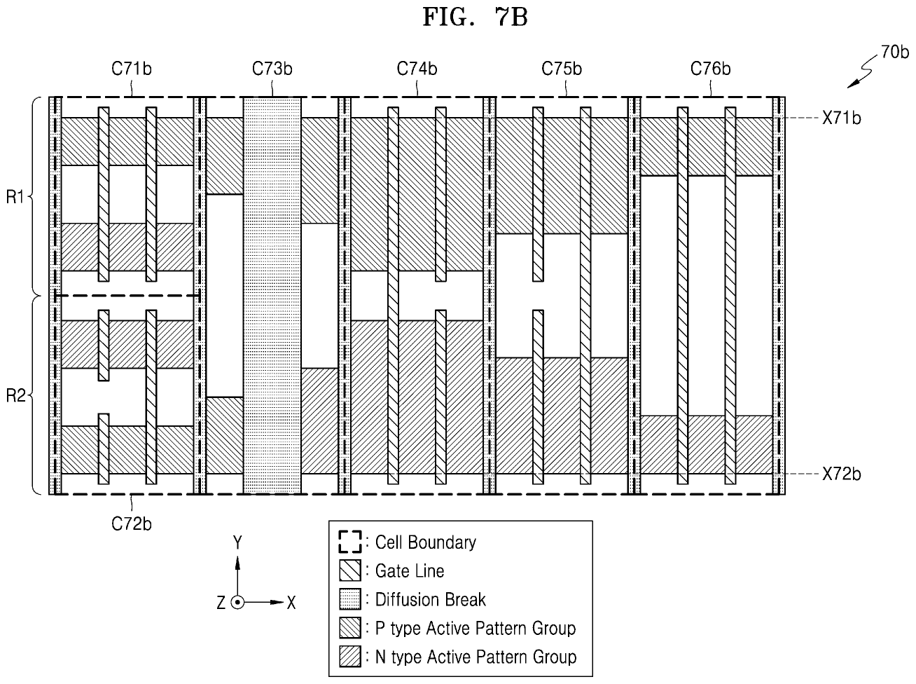

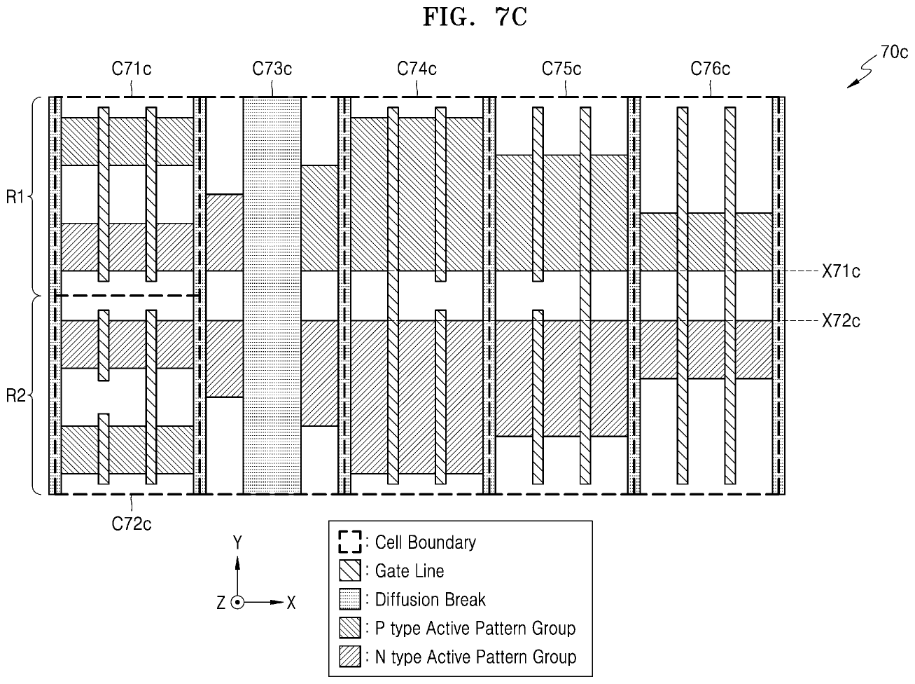

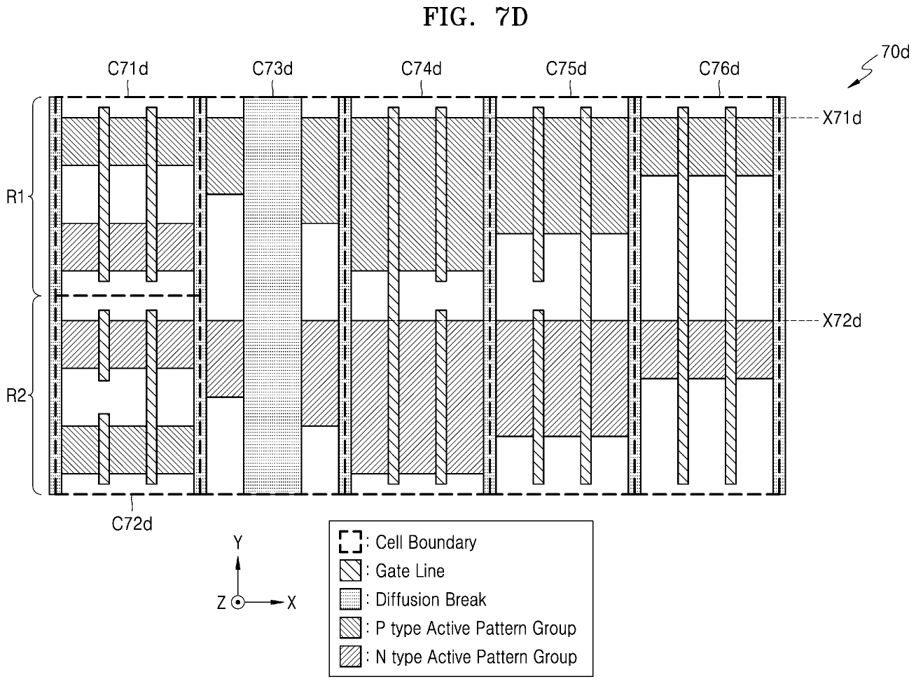

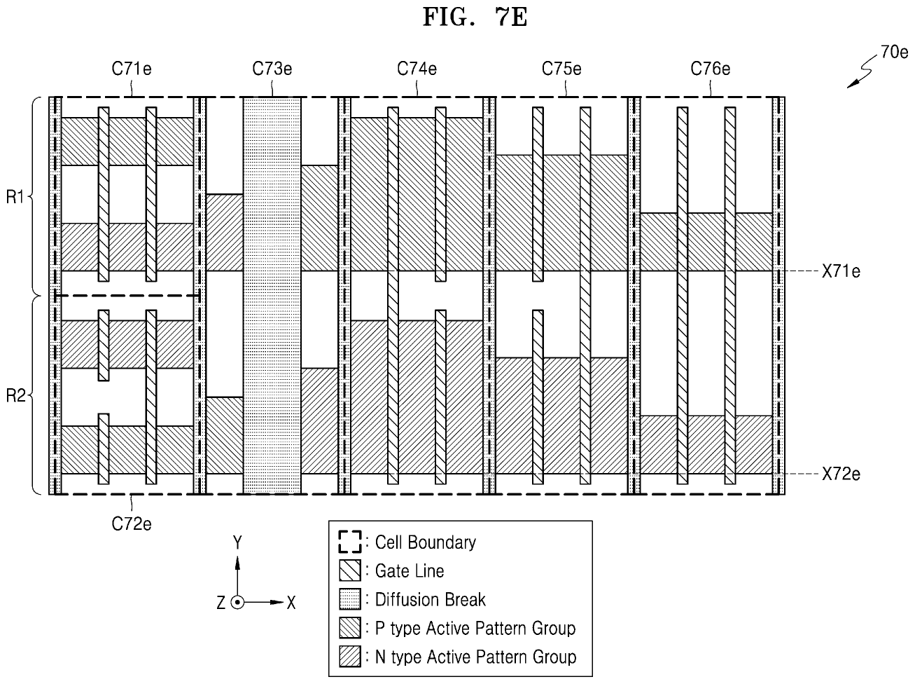

FIGS. 7A to 7E are plan views illustrating examples of layouts of an integrated circuit according to example embodiments. The plan views of FIGS. 7A to 7E illustrate active patterns (e.g., nanosheets) variously arranged in multi-height cells.

Referring to FIG. 7A, an integrated circuit 70a may include a first cell C71a in a first row R1, a second cell C72a in a second row R2, and third to sixth cells C73a to C76a continuously arranged in the first and second rows R1 and R2. The third cell C73a may be a buffer cell and may be between single-height cells, that is, the first and second cells C71a and C72a and a multi-height cell, that is, the fourth cell C74a. As illustrated in FIG. 7A, active pattern groups of the third cell C73a, that is, nanosheets may be in-bounded.

A multi-height cell may include active pattern groups of various widths (i.e., widths in the Y-axis direction). For example, the fourth cell C74a may include a nanosheet having a width that is greater than a width of a nanosheet of the fifth cell C75a, and the sixth cell C76a may include a nanosheet having a width that is less than the nanosheet of the fifth cell C75a. Nanosheets of the fourth to sixth cells C74a to C76a in the first row R1 may respectively have centers (e.g., centers in the Y-axis direction) overlapping a first line X71a extending in the X-axis direction. In addition, nanosheets of the fourth to sixth cells C74a to C76a in the second row R2 may respectively have centers (e.g., centers in the Y-axis direction) overlapping a second line X72a extending in the X-axis direction. Accordingly, the nanosheets of the fourth to sixth cells C74a to C76a may be mid-bounded.

Referring to FIG. 7B, an integrated circuit 70b may include a first cell C71b in a first row R1, a second cell C72b in a second row R2, and third to sixth cells C73b to C76b continuously arranged in the first and second rows R1 and R2. The third cell C73b may be a buffer cell and may be between single-height cells, that is, the first and second cells C71b and C72b and a multi-height cell, that is, the fourth cell C74b. As illustrated in FIG. 7B, active pattern groups of the third cell C73b, that is, nanosheets, may be out-bounded.

The fourth cell C74b may include a nanosheet having a width that is greater than a width of a nanosheet of the fifth cell C75b, and the sixth cell C76b may have a width that is less than the width of the nanosheet of the fifth cell C75b. Nanosheets of the fourth to sixth cells C74b to C76b in the first row R1 may respectively have boundaries overlapping a first line X71b extending in the X-axis direction and may be between the first line X71b and the second row R2. In addition, nanosheets of the fourth to sixth cells C74b to C76b in the second row R2 may respectively have boundaries overlapping a second line X72b extending in the X-axis direction and may be between the second line X72b and the first row R1. Accordingly, the nanosheets of the fourth to sixth cells C74b to C76b may be out-bounded.

Referring to FIG. 7C, an integrated circuit 70c may include a first cell C71c in a first row R1, a second cell C72c in a second row R2, and third to sixth cells C73c to C76c continuously arranged in the first and second rows R1 and R2. The third cell C73c may be a buffer cell and may be between single-height cells, that is, the first and second cells C71c and C72c and a multi-height cell, that is, the fourth cell C74c. As illustrated in FIG. 7C, active pattern groups of the third cell C73c, that is, nanosheets, may be in-bounded.

The fourth cell C74c may include a nanosheet having a width that is greater than a width of a nanosheet of the fifth cell C75c, and the sixth cell C76c may have a width that is less than the width of the nanosheet of the fifth cell C75c. The nanosheets of the fourth to sixth cells C74c to C76c in the first row R1 may respectively have boundaries overlapping a first line X71c extending in the X-axis direction, and the first line X71c may be between the second row R2 and the nanosheets of the fourth to sixth cells C74c to C76c in the first row R1. In addition, the nanosheets of the fourth to sixth cells C74c to C76c in the second row R2 may respectively have boundaries overlapping a second line X72c extending in the X-axis direction and the second line X72c may be between the first row R1 and the nanosheets of the fourth to sixth cells C74c to C76c in the second row R2. Accordingly, the nanosheets of the fourth to sixth cells C74c to C76c may be in-bounded.

Referring to FIG. 7D, an integrated circuit 70d may include a first cell C71d in a first row R1, a second cell C72d in a second row R2, and third to sixth cells C73d to C76d continuously arranged in the first and second rows R1 and R2. The third cell C73d may be a buffer cell and may be between single-height cells, that is, the first and second cells C71d and C72d, and a multi-height cell, that is, the fourth cell C74d.

The fourth cell C74d may include a nanosheet having a width that is greater than a width of a nanosheet of the fifth cell C75d, and the sixth cell C76d may have a width that is less than the width of the nanosheet of the fifth cell C75d. The nanosheets of the fourth to sixth cells C74d to C76d in the first row R1 may respectively have boundaries overlapping a first line X71d extending in the X-axis direction and may be between the first line X71d and the second row R2. In addition, the nanosheets of the fourth to sixth cells C74d to C76d in the second row R2 may respectively have boundaries overlapping a second line X72d extending in the X-axis direction, and the second line X72d may be between the first row R1 and the nanosheets of the fourth to sixth cells C74d to C76d in the second row R2.

Referring to FIG. 7E, an integrated circuit 70e may include a first cell C71e in a first row R1, a second cell C72e in a second row R2, and third to sixth cells C73e to C76e continuously arranged in the first and second rows R1 and R2. The third cell C73e may be a buffer cell and may be between single-height cells, that is, the first and second cells C71e and C72e and a multi-height cell, that is, the fourth cell C74e.

The fourth cell C74e may include a nanosheet having a width that is greater than a width of a nanosheet of the fifth cell C75e, and the sixth cell C76e may include a nanosheet having a width that is less than the width of the nanosheet of the fifth cell C75e. The nanosheets of the fourth to sixth cells C74e to C76e in the first row R1 may respectively have boundaries overlapping a first line X71e extending in the X-axis direction, and the first line X71e may be between the second row R2 and the nanosheets of the fourth to sixth cells C74e to C76e in the first row R1. In addition, the nanosheets of the fourth to sixth cells C74e to C76e in the second row R2 may respectively have boundaries overlapping a second line X72e extending in the X-axis direction and may be between the second line X72e and the first row R1.

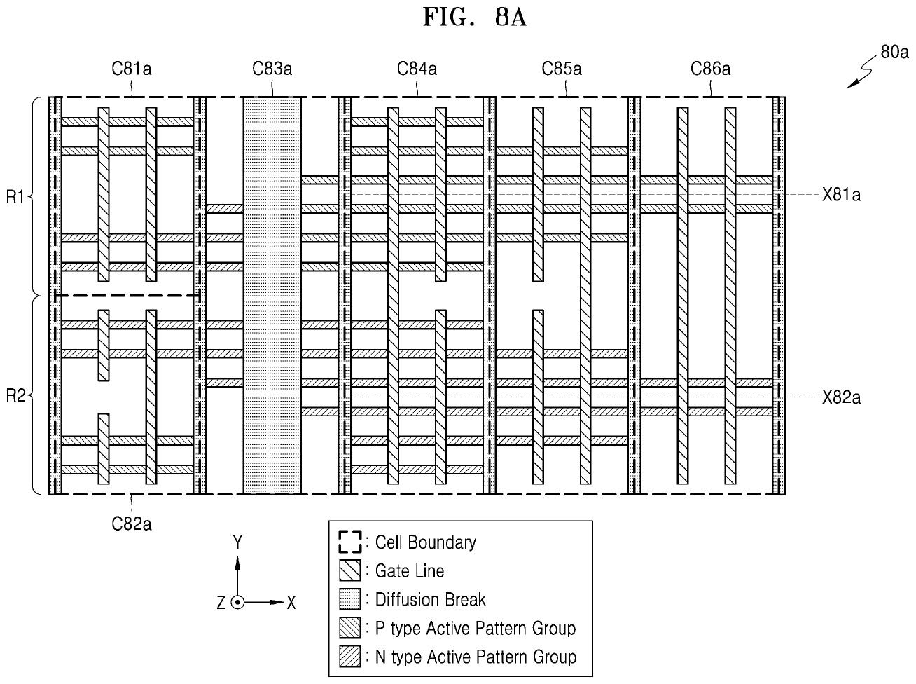

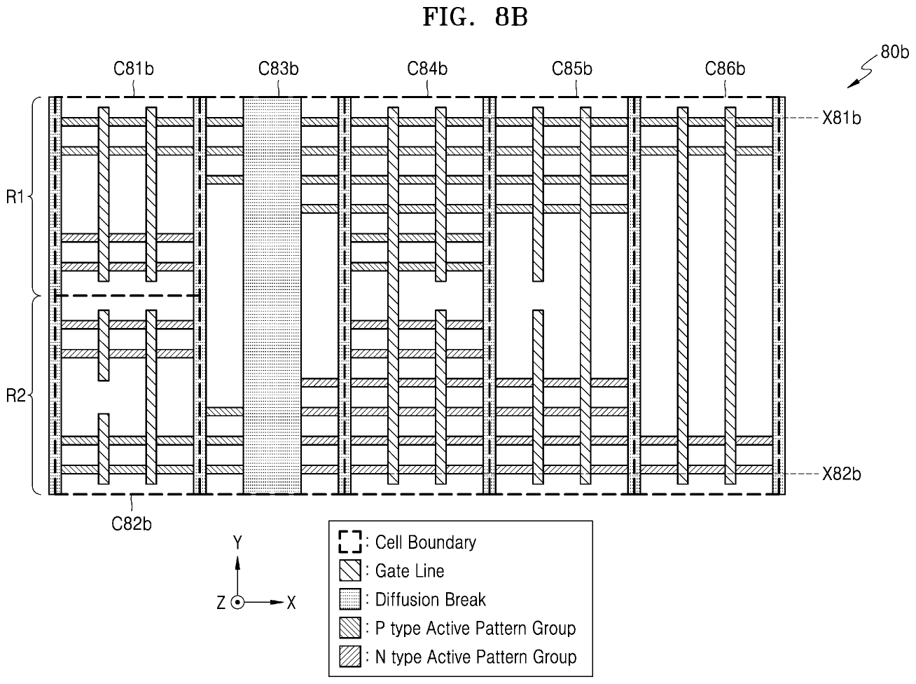

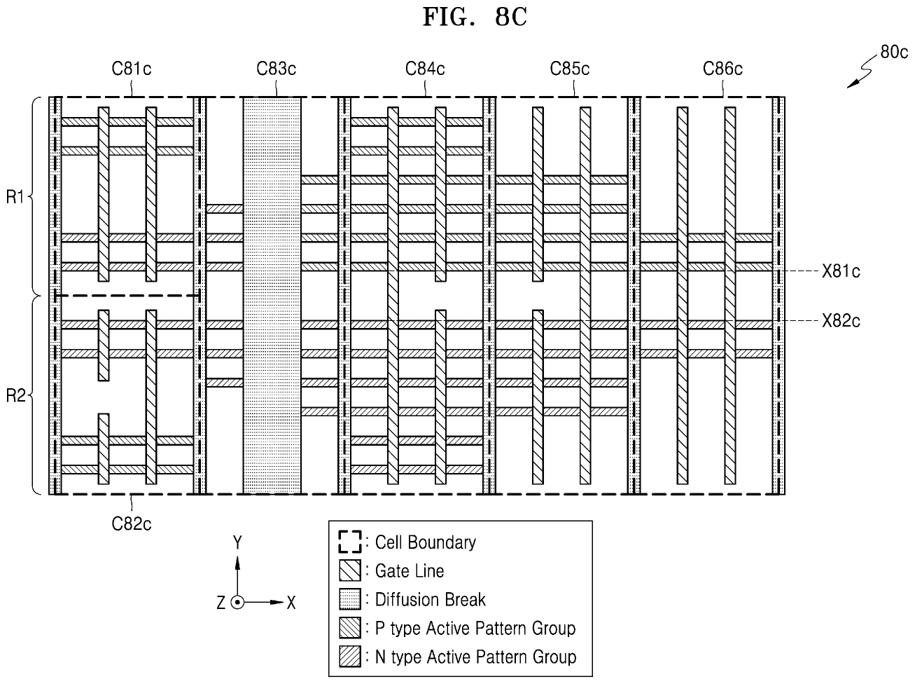

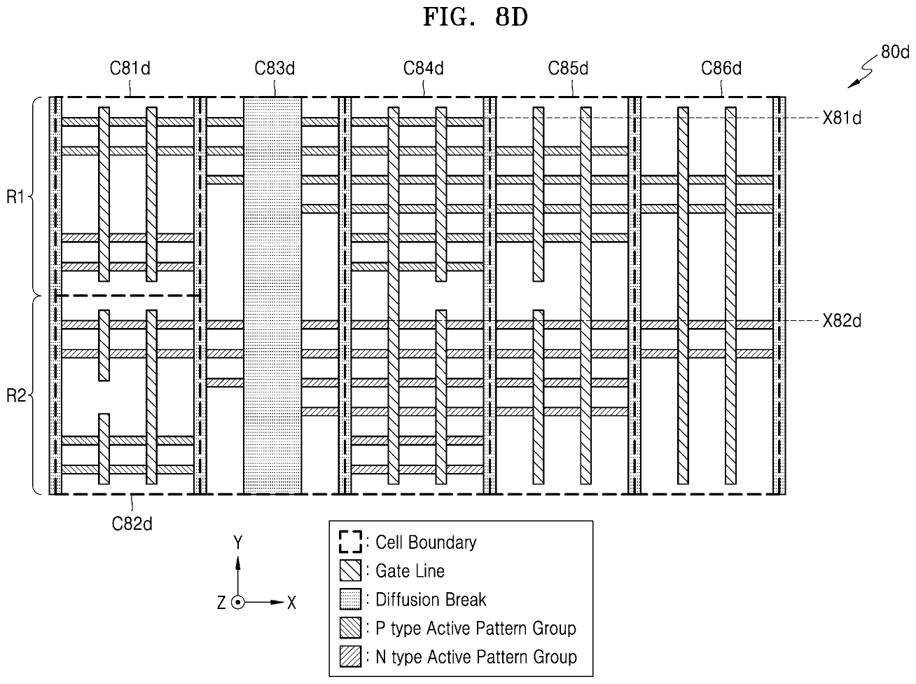

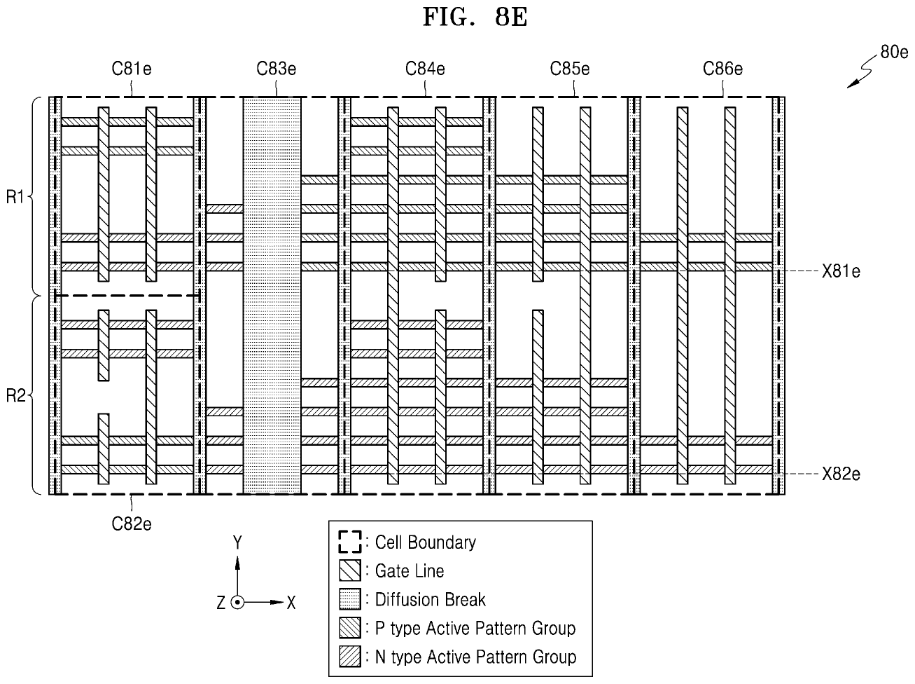

FIGS. 8A to 8E are plan views illustrating examples of layouts of an integrated circuit according to example embodiments. The plan views of FIGS. 8A to 8E illustrate active pattern groups that are variously arranged in multi-height cells. In FIGS. 8A to 8E, one active pattern group may include at least one fin (i.e., a fin-shaped active pattern).

Referring to FIG. 8A, an integrated circuit 80a may include a first cell C81a in a first row R1, a second cell C82a in a second row R2, and third to sixth cells C83a to C86a continuously arranged in the first and second rows R1 and R2. The third cell C83a may be a buffer cell and may be between single-height cells, that is, the first and second cells C81a and C82a and a multi-height cell, that is, the fourth cell C84a. As illustrated in FIG. 8A, active pattern groups of the third cell C83a may be in-bounded.

A multi-height cell may include active pattern groups of various widths, and the active pattern groups of wider widths may include more active patterns, that is, more fins. For example, the fourth cell C84a may include more fins than the fifth cell C85a, and the sixth cell C86a may include fewer fins than the fifth cell C85a. The active pattern groups of the fourth to sixth cells C84a to C86a in the first row R1 may respectively have centers (e.g., centers in the Y-axis direction) overlapping a first line X81a extending in the X-axis direction. In addition, the active pattern groups of the fourth to sixth cells C84a to C86a in the second row R2 may respectively have centers (e.g., centers in the Y-axis direction) overlapping a second line X82a extending in the X-axis direction. Accordingly, the active pattern groups of the fourth to sixth cells C84a to C86a may be mid-bounded.

Referring to FIG. 8B, an integrated circuit 80b may include a first cell C81b in a first row R1, a second cell C82b in a second row R2, and third to sixth cells C83b to C86b continuously arranged in the first and second rows R1 and R2. The third cell C83b may be a buffer cell and may be between single-height cells, that is, the first and second cells C81b and C82b and a multi-height cell, that is, the fourth cell C84b. As illustrated in FIG. 8B, active pattern groups of the third cell C83b may be out-bounded.

The fourth cell C84b may include more fins than the fifth cell C85b, and the sixth cell C86b may include fewer fins than the fifth cell C85b. The active pattern groups of the fourth to sixth cells C84b to C86b in the first row R1 may respectively have boundaries overlapping a first line X81b extending in the X-axis direction and may be between the first line X81b and the second row R2. In addition, the active pattern groups of the fourth to sixth cells C84b to C86b in the second row R2 may respectively have boundaries overlapping a second line X82b extending in the X-axis direction and may be between the second line X82b and the first row R1. Accordingly, the active pattern groups of the fourth to sixth cells C84b to C86b may be out-bounded.

Referring to FIG. 8C, an integrated circuit 80c may include a first cell C81c in a first row R1, a second cell C82c in a second row R2, and third to sixth cells C83c to C86c continuously arranged in the first and second rows R1 and R2. The third cell C83c may be a buffer cell and may be between single-height cells, that is, the first and second cells C81c and C82c and a multi-height cell, that is, the fourth cell C84c. As illustrated in FIG. 8C, active pattern groups of the third cell C83c may be in-bounded.

The fourth cell C84c may include more fins than the fifth cell C85c, and the sixth cell C86c may include fewer fins than the fifth cell C85c. Active pattern groups of the fourth to sixth cells C84c to C86c in the first row R1 may respectively have boundaries overlapping a first line X81c extending in the X-axis direction, and the first line X81c may be between the second row R2 and the active pattern groups of the fourth to sixth cells C84c to C86c in the first row R1. In addition, active pattern groups of the fourth to sixth cells C84c to C86c in the second row R2 may respectively have boundaries overlapping a second line X82c extending in the X-axis direction and the second line X82c may be between the first row R1 and the active pattern groups of the fourth to sixth cells C84c to C86c in the second row R2. Accordingly, the active pattern groups of the fourth to sixth cells C84c to C86c may be in-bounded.

Referring to FIG. 8D, an integrated circuit 80d may include a first cell C81d in a first row R1, a second cell C82d in a second row R2, and third to sixth cells C83d to C86d continuously arranged in the first and second rows R1 and R2. The third cell C83d may be a buffer cell and may be between single-height cells, that is, the first and second cells C81d and C82d, and a multi-height cell, that is, the fourth cell C84d.

The fourth cell C84d may include more fins than the fifth cell C85d, and the sixth cell C86d may include fewer fins than the fifth cell C85d. Active pattern groups of the fourth to sixth cells C84d to C86d in the first row R1 may respectively have boundaries overlapping a first line X81d extending in the X-axis direction and may be between the first line X81d and the second row R2. In addition, active pattern groups of the fourth to sixth cells C84d to C86d in the second row R2 may respectively have boundaries overlapping a second line X82d extending in the X-axis direction and the second line X82d may be between the first row R1 and the active pattern groups of the fourth to sixth cells C84d to C86d in the second row R2.

Referring to FIG. 8E, an integrated circuit 80e may include a first cell C81e in a first row R1, a second cell C82e in a second row R2, and third to sixth cells C83e to C86e continuously arranged in the first and second rows R1 and R2. The third cell C83e may be a buffer cell and may be between single-height cells, that is, the first and second cells C81e and C82e and a multi-height cell, that is, the fourth cell C84e.

The fourth cell C84e may include more fins than the fifth cell C85e, and the sixth cell C86e may include fewer fins than the fifth cell C85e. Active pattern groups of the fourth to sixth cells C84e to C86e in the first row R1 may respectively have boundaries overlapping a first line X81e extending in the X-axis direction, and the first line X81e may be between the second row R2 and the active pattern groups of the fourth to sixth cells C84e to C86e in the first row R1. In addition, active pattern groups of the fourth to sixth cells C84e to C86e in the second row R2 may respectively have boundaries overlapping a second line X82e extending in the X-axis direction and may be between the second line X82e and the first row R1.

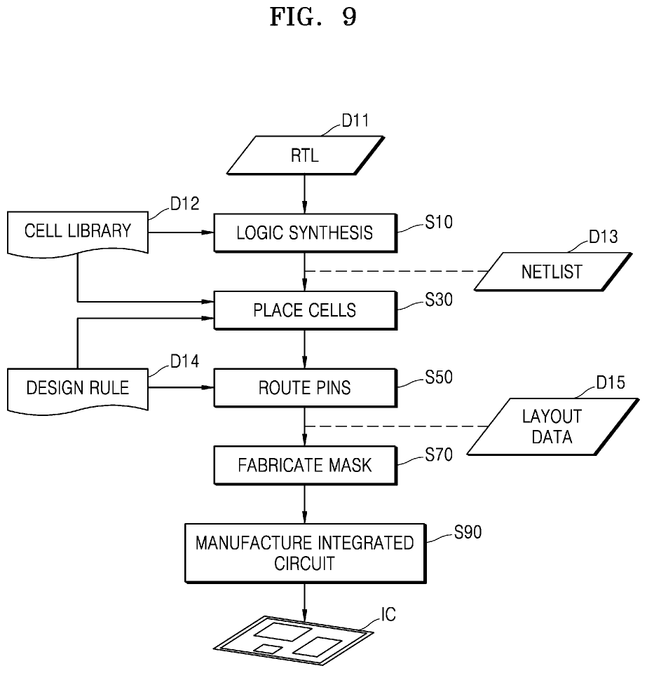

FIG. 9 is a flowchart illustrating a method of manufacturing an integrated circuit (IC), according to an example embodiment. For example, the flowchart of FIG. 9 illustrates an example of a method of manufacturing an IC including standard cells. As illustrated in FIG. 9, the method of manufacturing an IC may include a plurality of operations S10, S30, S50, S70, and S90.

A cell library (or a standard cell library) D12 may include information on standard cells, for example, information on functions, characteristics, layouts, and so on. In some embodiments, the cell library D12 may define single-height cells and multi-height cells. In some embodiments, the cell library D12 may define buffer cells between single-height cells and multi-height cells. In some embodiments, the cell library D12 may define multi-height cells, including active pattern groups of various widths, respectively.

A design rule D14 may include requirements that have to be complied with in a layout of an IC. For example, the design rule D14 may include requirements for a space between patterns in the same layer, a minimum width of a pattern, a routing direction of a wiring layer, and so on. In some embodiments, the design rule D14 may define a minimum width of an active pattern, a shortest separation distance between active patterns, and so on.

In operation S10, a logic synthesis operation of generating a netlist D13 from RTL data D11 may be performed. For example, a semiconductor design tool (e.g., a logic synthesis tool) performs logic synthesis with reference to the cell library D12 from RTL data D11 generated as a VHSIC hardware description language (VHDL) and a hardware description language (HDL), such as Verilog, to generate a bitstream or the netlist D13 including a netlist. The netlist D13 may correspond to an input of place and routing, which will be described below.

In operation S30, cells may be placed. For example, the semiconductor design tool (e.g., a P&R tool) may place standard cells used in the netlist D13 with reference to the cell library D12 and the design rule D14. In some embodiments, when a multi-height cell is placed, a semiconductor design tool may place a buffer cell between single-height cells and a multi-height cell.

In operation S50, pins of cells may be routed. For example, the semiconductor design tool may generate interconnections electrically connecting output pins to input pins of the placed standard cells and generate layout data D15 defining the placed standard cells and the generated interconnections. The interconnections may include vias in a via layer and/or patterns in a wiring layer. The layout data D15 may have a format, such as GDSII, and may include geometric information of cells and interconnections. The semiconductor design tool may refer to the design rule D14 while routing pins of cells. The layout data D15 may correspond to an output of place and routing. Only operation S50 or both operation S30 and operation S50 may be referred to as a method of designing an IC.

In operation S70, an operation of manufacturing a mask may be performed. For example, in photolithography, optical proximity correction (OPC) for correcting distortion, such as refraction, caused by characteristics of light may be applied to the layout data D15. Patterns on a mask may be defined to form the patterns on a plurality of layers based on the data to which OPC is applied, and at least one mask (or photomask) for forming the pattern of each of the plurality of layers may be manufactured. In some embodiments, a layout of an IC may be limitedly modified in operation S70, and the limited modification of the IC in operation S70 is post-processing for optimizing a structure of an IC and may be referred to as design polishing.

In operation S90, an operation of fabricating an IC may be performed. For example, the IC may be manufactured by patterning a plurality of layers by using at least one mask fabricated in operation S70. A front-end-of-line (FEOL) may include, for example, planarizing and cleaning a wafer, forming trenches, forming wells, forming gate electrodes, and forming a source and a drain, and individual elements, such as a transistor, a capacitor, and a resistor, may be formed in a substrate by the FEOL. In addition, a back-end-of-line (BEOL) may include, for example, performing silicidation of a gate region, a source region, and a drain region, adding a dielectric, performing planarization, forming a hole, adding a metal layer, forming a via, forming a passivation layer, and so on, and individual elements, such as a transistor, a capacitor, and a resistor, may be interconnected to each other by the BEOL. In some embodiments, a middle-of-line (MOL) may be performed between the FEOL and the BEOL, and contacts may be formed on the individual elements. Subsequently, the IC may be packaged in a semiconductor package and may be used as a component in various applications.

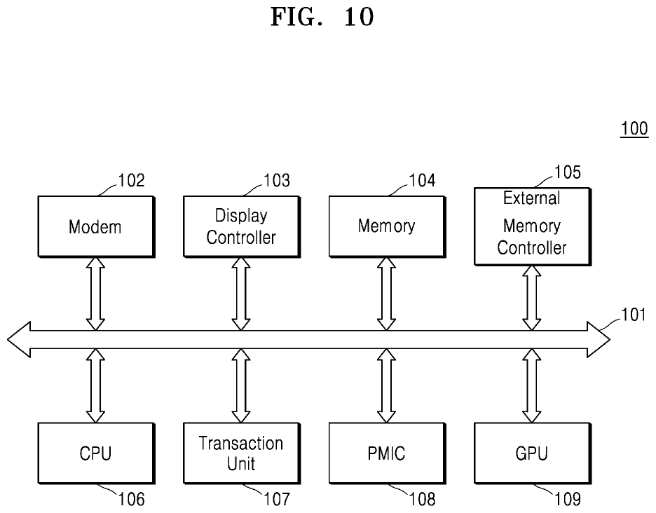

FIG. 10 is a block diagram illustrating a system-on-chip 100 according to an example embodiment. The system-on-chip 100 may be a semiconductor device and include an integrated circuit according to an example embodiment. The system on chip 100 implements complex blocks, such as intellectual property (IP) for performing various functions, in one chip, and may be designed by a method of designing an IC, according to example embodiments, and thus, the system on chip 100 may have optimal performance and efficiency. Referring to FIG. 10, the system on chip 100 may include a modem 102, a display controller 103, a memory 104, an external memory controller 105, a central processing unit (CPU) 106, a transaction unit 107, a power management integrated circuit (PMIC) 108, and a graphics processing unit (GPU) 109, and respective functional blocks of the system on chip 100 may communicate with each other via a system bus 101.

The CPU 106 that may control an operation of the system on chip 100 in an uppermost layer may control operations of other functional blocks, that is, the modem 102, the display controller 103, the memory 104, the external memory controller 105, the CPU 106, the transaction unit 107, a the PMIC 108, and the GPU 109. The modem 102 may demodulate a signal received from the outside of the system on chip 100 or modulate a signal generated by the system on chip 100 and transmit the demodulated or modulated signal to the outside. The external memory controller 105 may control an operation of transmitting and receiving data to and from an external memory device connected to the system on chip 100. For example, programs and/or data stored in the external memory device may be provided to the CPU 106 or the GPU 109 by control of the external memory controller 105. The GPU 109 may perform program instructions related to graphics processing. The GPU 109 may also receive graphic data through the external memory controller 105 and also transmit the graphic data processed by the GPU 109 to the outside of the system on chip 100 through the external memory controller 105. The transaction unit 107 may monitor data transactions of the respective functional blocks, and the PMIC 108 may control power supplied to the respective functional blocks according to the control of the transaction unit 107. The display controller 103 may transmit the data generated by the system on chip 100 to a display by controlling the display (or a display device) outside the system on chip 100. The memory 104 may include a non-volatile memory, such as electrically erasable programmable read-only memory (EEPROM) or flash memory, and may also include a volatile memory, such as dynamic random access memory (DRAM) or static random access memory (SRAM).

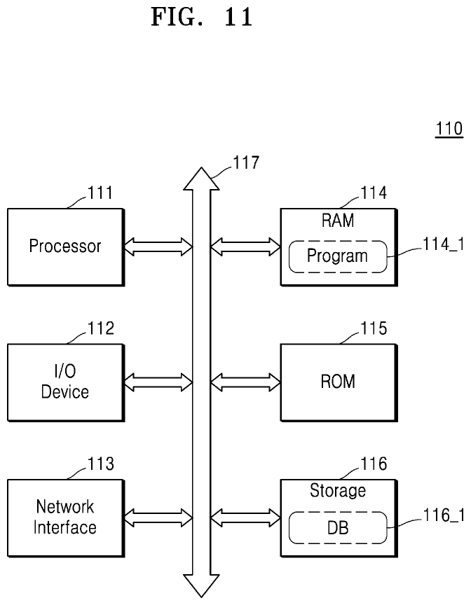

FIG. 11 is a block diagram illustrating a computing system 110 including a memory for storing a program, according to an example embodiment. In the method of designing an integrated circuit according to an example embodiment, for example, at least some of the operations in the flowchart described above may be performed by the computing system (or a computer) 110.

The computing system 110 may include a stationary computing system, such as a desktop computer, a workstation, and a server, or may include a portable computing system, such as a laptop computer. As illustrated in FIG. 11, the computing system 110 may include a processor 111, input/output (I/O) devices 112, a network interface 113, a random access memory (RAM) 114, a read only memory (ROM) 115, and a storage 116. The processor 111, the I/O devices 112, the network interface 113, the RAM 114, the ROM 115, and the storage 116 may be connected to a bus 117 and may communicate with each other via the bus 117.

The processor 111 may be referred to as a processing unit and may include at least one core, which may perform any instruction set (e.g., Intel Architecture-32 (IA-32), 64-bit-extended IA-32, x86-64, PowerPC, Sparc, MIPS, ARM, IA-64, and so on), such as a micro-processor, an application processor (AP), a digital signal processor (DSP), or a graphics processing unit (GPU). For example, the processor 111 may access a memory, that is, the RAM 114 or the ROM 115, via the bus 117, and perform instructions stored in the RAM 114 and the ROM 115.

The RAM 114 may store a program 114_1 or at least a part thereof for a method of designing an integrated circuit, according to an example embodiment, and the program 114_1 may cause the processor 111 to perform the method of designing the integrated circuit, for example, at least some of the operations included in the method of FIG. 9. That is, the program 114_1 may include a plurality of instructions executable by the processor 111, and the plurality of instructions included in the program 114_1 may cause the processor 111 to perform at least some of the operations included in, for example, the flowcharts described above.

The storage 116 may not lose stored data even when the power supplied to the computing system 110 is off. For example, the storage 116 may also include a non-volatile memory device and may also include a storage medium, such as a magnetic tape, an optical disk, or a magnetic disk. In addition, the storage 116 is removable from the computing system 110. The storage 116 may store the program 114_1 according to an example embodiment, and before the program 114_1 is executed by the processor 111, the program 114_1 or at least a part thereof may be loaded into the RAM 114 from the storage 116. Alternatively, the storage 116 may store a file written in a programming language, and the program 114_1 generated from the file by a compiler or the like or at least a part thereof may be loaded into the RAM 114. In addition, as illustrated in FIG. 11, the storage 116 may store a database (DB) 116_1, and the database 116_1 may include information required for designing an integrated circuit, for example, information on designed blocks, the cell library D12 of FIG. 9, and/or the design rule D14.

The storage 116 may also store data to be processed by the processor 111 or data processed by the processor 111. That is, the processor 111 may generate data by processing the data stored in the storage 116 according to the program 114_1 and also store the generated data in the storage 116. For example, the storage 116 may store the RTL data D11, the netlist D13, and/or the layout data D15 of FIG. 9.

The I/O devices 112 may include an input device, such as a keyboard or a pointing device, and include an output device, such as a display device or a printer. For example, a user may also trigger execution of the program 114_1 by using the processor 111 through the I/O devices 112, also read the RTL data D11 and/or the netlist D13 of FIG. 9, and also check the layout data D15 of FIG. 9.

The network interface 113 may provide an access to an external network of the computing system 110. For example, the external network may include multiple computing systems and communication links, and the communication links may include wired links, optical links, wireless links, or any other type of links.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure. As used herein the term “and/or” includes any and all combinations of one or more of the associated listed items.

While the inventive concept has been particularly shown and described with reference to embodiments thereof, it will be understood that various changes in form and details may be made therein without departing from the scope of the following claims.

What is claimed is:

1. An integrated circuit comprising:
a first cell in a first row and a second cell in a second row, wherein the first and second rows are adjacent to each other and extend in a first direction; and
a third cell in the first row and the second row,
wherein each of the first cell and the second cell comprises a first active pattern group including at least one first active pattern that extends in the first direction and has a first conductivity type,
the third cell comprises a second active pattern group including at least one second active pattern that extends in the first direction in the first row and has the first conductivity type, and
an effective channel width of the second active pattern group is wider than an effective channel width of the first active pattern group.

2. The integrated circuit of claim 1, wherein
each of the first cell and the second cell further comprises a third active pattern group including at least one third active pattern that extends in the first direction and has a second conductivity type,
the third cell further comprises a fourth active pattern group including at least one fourth active pattern that extends in the first direction in the second row and has the second conductivity type, and
an effective channel width of the fourth active pattern group is wider than an effective channel width of the third active pattern group.

3. The integrated circuit of claim 2, wherein the third cell further comprises at least one gate electrode that extends in a second direction that is perpendicular to the first direction, and the at least one gate electrode overlaps the second active pattern group and the fourth active pattern group in a third direction that is perpendicular to the first direction and the second direction.

4. The integrated circuit of claim 1, further comprising a first power line that extends in the first direction on a boundary between the first row and the second row and is shared by the first cell and the second cell,
wherein the first power line passes through the third cell.

5. The integrated circuit of claim 1, further comprising a fourth cell in the first row and the second row,
wherein the fourth cell comprises a fifth active pattern group including at least one fifth active pattern that extends in the first direction in the first row and has the first conductivity type, and
an effective channel width of the fifth active pattern group is different from the effective channel width of the second active pattern group.

6. The integrated circuit of claim 5, wherein the second active pattern group and the fifth active pattern group each comprise a boundary overlapping a line extending in the first direction and are between the line and the second row.

7. The integrated circuit of claim 5, wherein
the second active pattern group and the fifth active pattern group each comprise a boundary overlapping a line extending in the first direction, and
the line is between the second active pattern group and the second row and is between the fifth active pattern group and the second row.

8. The integrated circuit of claim 5, wherein the second active pattern group and the fifth active pattern group comprise respective centers in a second direction that is perpendicular to the first direction, and the centers of the second active pattern group and the fifth active pattern group are aligned along the first direction.

9. The integrated circuit of claim 1, further comprising first and second gates extending in a second direction that is perpendicular to the first direction,
wherein the first gate overlaps the at least one first active pattern in a third direction that is perpendicular to the first direction and the second direction, and the second gate overlaps the at least one second active pattern in the third direction.

10. The integrated circuit of claim 1, further comprising first and second gates extending in a second direction that is perpendicular to the first direction,
wherein the least one first active pattern comprises a first nanosheet passing through the first gate, and the least one second active pattern comprises a second nanosheet passing through the second gate.

11. An integrated circuit comprising:
a first cell in a first row and a second cell in a second row, wherein the first and second rows are adjacent to each other and extend in a first direction;
a third cell in the first row and the second row; and
a buffer cell in the first row and the second row, wherein the buffer cell is between the first cell and the third cell and is between the second cell and the third cell,
wherein the third cell comprises a first active pattern group including at least one first active pattern that extends in the first direction in the first row and has a first conductivity type,
the buffer cell comprises a second active pattern group including at least one second active pattern that extends in the first direction in the first row and has the first conductivity type, and
an effective channel width of the second active pattern group is narrower than an effective channel width of the first active pattern group.

12. The integrated circuit of claim 11, wherein
each of the first cell and the second cell comprises a third active pattern group including at least one third active pattern that extends in the first direction and has the first conductivity type, and
the effective channel width of the second active pattern group is wider than an effective channel width of the third active pattern group.

13. The integrated circuit of claim 12, wherein
the buffer cell further comprises a fourth active pattern group including at least one fourth active pattern that extends in the first direction in the second row and has the first conductivity type, and
an effective channel width of the fourth active pattern group is narrower than the effective channel width of the first active pattern group and is wider than the effective channel width of the third active pattern group.

14. The integrated circuit of claim 11, wherein the buffer cell further comprises at least one diffusion break extending in a second direction that is perpendicular to the first direction.

15. The integrated circuit of claim 11, wherein the buffer cell comprises a tie cell that is configured to generate an output signal having a constant level.

16. The integrated circuit of claim 11, further comprising first and second gates extending in a second direction that is perpendicular to the first direction,
wherein the first gate overlaps the at least one first active pattern in a third direction that is perpendicular to the first direction and the second direction, and the second gate overlaps the at least one second active pattern in the third direction.

17. The integrated circuit of claim 11, further comprising first and second gates extending in a second direction that is perpendicular to the first direction,
wherein the least one first active pattern comprises a first nanosheet passing through the first gate, and the least one second active pattern comprises a second nanosheet passing through the second gate.

18. An integrated circuit including cells arranged in a plurality of rows extending in a first direction, the integrated circuit comprising:
a first active pattern group including at least one first active pattern that extends in the first direction in a first row among the plurality of rows and has a first conductivity type;
a second active pattern group including at least one second active pattern that extends in parallel to the first active pattern group in the first row and has a second conductivity type; and
a third active pattern group including at least one third active pattern that extends in the first direction in the first row and has the first conductivity type,
wherein an effective channel width of the third active pattern group is wider than an effective channel width of the first active pattern group.

19. The integrated circuit of claim 18, further comprising a fourth active pattern group including at least one fourth active pattern that extends in parallel to the third active pattern group in a second row among the plurality of rows and has the second conductivity type, wherein the second row is adjacent to the first row, and
wherein an effective channel width of the fourth active pattern group is wider than an effective channel width of the second active pattern group.

20. The integrated circuit of claim 18, further comprising a fifth active pattern group including at least one fifth active pattern that extends in the first direction in the first row between the first active pattern group and the third active pattern group and has the first conductivity type,
wherein an effective channel width of the fifth active pattern group is wider than the effective channel width of the first active pattern group and is narrower than the effective channel width of the third active pattern group.
